(19) United States
(12) Patent Application Publication
(10) Pub. No.: US 2010/0112334 A1
(43) Pub. Date: May 6, 2010

(54) SILICON CARBIDE-BASED POROUS BODY AND METHOD OF FABRICATING THE SAME

(76) Inventors: Mun-Kyu Cho, Gyeongsangbuk-do (KR); Doo-Hoa Jeong, Republic of Korea (KR); Gi-Gen Hong, Republic of Korea (KR)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/532,127

(22) PCT Filed: Mar. 22, 2007
(86) PCT No.: PCT/KR2007/001396

§ 371 Date: Sep. 18, 2009

(51) Int. Cl. B32B 3/26; C23C 16/44

(52) U.S. Cl. 428/317.9; 427/255.12

(57) ABSTRACT

Disclosed are a silicon carbide-based porous body and a method of fabricating the same. The silicon carbide-based porous body is formed by burning silicon carbide-based particles, and includes Si-N- or Si-N-O-based acicular particles grown to have a needle shape on the surfaces defining the pores in the porous body. Further, the method of fabricating a silicon carbide-based porous body includes forming a pre-molded product using silicon carbide-based particles having a purity of 95% to 99%, and thermally treating the pre-molded product in a kiln in a nitrogen atmosphere having partial pressure of 0.5 atm to 2 atm, thus growing Si-N- or Si-N-O-based acicular particles having a needle shape on the surfaces defining the pores in the porous body.

### TECHNICAL FIELD

The present invention relates to a ceramic porous body and a method of fabricating the same, and more particularly, to a silicon carbide-based porous body, which includes acicular particles having a needle shape on the surfaces defining the pores in the porous body, and to a method of fabricating the same.

### BACKGROUND ART

Exhaust gas generated from diesel engines, power generators, and incinerators includes great amounts of fine carbon soot particles. In particular, as the diesel engine adopts a common rail system, the discharge of nano-sized ultrafine particles is greatly increasing. Thus, in order to effectively remove such particles, there is proposed a post-treatment device for removing fine carbon soot particles using a porous filter mounted in an exhaust pipe. For the porous filter used in the post-treatment device, various materials, including cordierite, mullite, alumina, silicon carbide (SiC), or aluminum nitride (AIN), have been studied. Among these, silicon carbide, having high heat resistance, high mechanical strength, and high thermal conductivity, is particularly useful.

Japanese Unexamined Patent Publication No. 2002-359128 discloses a method of manufacturing a silicon carbide (SiC) porous body, comprising binding silicon carbide (SiC) particles using oxides of silicon (Si), aluminum (Al), and alkali earth metal.

However, the method disclosed in Japanese Unexamined Patent Publication No. 2002-359128 suffers because the pores have a large size of tens of μm, and therefore nano-sized ultrafine carbon soot particles cannot be effectively adsorbed, undesirably decreasing filtration performance.

### DISCLOSURE OF THE INVENTION

### Technical Tasks to be Solved by the Invention

The present invention has been made keeping in mind the above problems encountered in the related art, and an object of the present invention is to provide a silicon carbide-based porous body, having superior thermal impact resistance and increased filtration properties, and a method of fabricating the same.

### Technical Solution

According to one aspect of the present invention, a silicon carbide-based porous body is provided. The silicon carbide-based porous body may be formed by burning silicon carbide and/or silicon particles having a purity of 95% to 99%, and may include Si-N- or Si-N-O-based acicular particles grown to have a needle shape on the surfaces defining the pores in the porous body.

According to another aspect of the present invention, a method of fabricating a silicon carbide-based porous body is provided.

This method may include forming a pre-molded product using silicon carbide particles having a purity of 95% to 99%, and thermally treating the pre-molded product in a kiln in a nitrogen atmosphere having partial pressure ranging from 0.5 atm to 2 atm, thus growing Si-N- or Si-N-O-based acicular particles having a needle shape on the surfaces defining the pores in the porous body.

As such, the thermal treatment may be conducted at a temperature ranging from 1400° C. to 1600° C. for a period of time ranging from 20 min to 60 min.

### Advantageous Effects

According to the present invention, a silicon carbide-based porous body having superior thermal impact resistance and improved filtration properties can be provided by controlling the purity of material particles and by forming acicular particles on the surfaces defining the pores in the porous body.

### BRIEF DESCRIPTION OF DRAWINGS

FIG. 1 shows a silicon carbide-based porous body comprising main material particles bound to each other, capable of filtering fine carbon soot particles, according to the present invention.

### BEST MODE FOR CARRYING OUT THE INVENTION

Hereinafter, preferred embodiments of the present invention are described in detail, with reference to the appended drawing. However, the present invention is not limited to the examples disclosed herein but may be variously embodied. Further, the examples of the present invention are provided to allow the disclosed contents to be thoroughly understood and to sufficiently convey the spirit of the present invention to those skilled in the art.

In the present invention, SiC and/or Si, which are used as main material particles, are bound to each other not using an additional oxide, but through high-temperature melting of impurities contained in the main material particles, while controlling the purity of the main material particles. Further, in order to efficiently adsorb and filter nano-sized fine carbon soot particles, pluralities of fine acicular particles are formed on the surfaces of the main material particles to thus induce the adsorption of fine carbon soot particles, thereby increasing filtration efficiency.

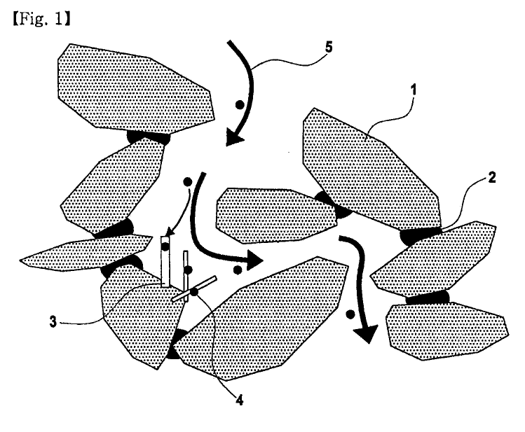

FIG. 1 shows the silicon carbide-based porous body comprising main material particles bound to each other, capable of filtering fine carbon soot particles, according to the present invention.

As shown in FIG. 1, in the case of main material particles 1 composed of SiC and/or Si, a product for industrial purposes contains oxides, such as SiO₂, Fe₂O₃, Al₂O₃, K₂O, and Na₂O, as impurities. The purity of the main material particles 1 is determined depending on the amount of impurities. When the purity of the main material particles 1 is less than 95%, the amount of impurities is too large, and thus the amount of a bound impurity phase 2 formed by the melting of the impurities in a high-temperature burning process becomes increased, consequently decreasing thermal impact resistance. On the other hand, when the purity is larger than 99%, the amount of impurities is too small, and thus a bound impurity phase 2 is not formed in an amount large enough to bind the particles to each other, undesirably decreasing thermal impact resistance.

The particles, such as SiC and Si, react with nitrogen gas (N₂), to thus produce Si-N- or Si-N-O-based acicular particles 3. Such acicular particles 3 have a nano-sized fine needle shape and are produced on the surfaces of main constituent materials, that is, on the surfaces defining the pores in the porous body formed through thermal treatment. When all the main material particles 1 are converted into the acicular particles 3, the pore size is considerably decreased and the flow of exhaust gas 5 is blocked. Therefore, it is important to control the above conversion. Furthermore, near the acicular particles 3, the flow of exhaust gas is turbulent. As such, since floating fine carbon soot particles 4 are caused to flow toward the surface of the acicular particles 3, the fine carbon soot particles 4 are adsorbed on the acicular particles 3 while colliding with the acicular particles.

In the method of fabricating the silicon carbide-based porous body according to the present invention, silicon carbide-based particles having a purity of 95% to 99% are used as main material particles to thus produce a pre-molded product, which is then thermally treated in a kiln. During the thermal treatment, the conversion of the material particles into the acicular particles 3 is determined by partial pressure of nitrogen gas to be supplied as an atmosphere gas upon thermal treatment, and by thermal treatment conditions. That is, when the partial pressure of nitrogen gas is smaller than 0.5 atm, the conversion of the main material particles 1 into the Si-N- or Si-N-O-based acicular particles 3 through decomposition and nitrification is low. On the other hand, when the partial pressure is larger than 2 atm, nitrification rapidly takes place, undesirably clogging the pores with the obtained acicular particles 3. Consequently, upon the thermal treatment, the partial pressure of nitrogen gas preferably ranges from 0.5 atm to 2 atm. Furthermore, when the temperature of thermal treatment is lower than 1400° C. or the reaction time is shorter than 20 min, it is difficult to sufficiently form acicular particles 3, and thus the filtration efficiency is low or the main material particles are weakly bound, resulting in decreased thermal impact resistance. On the other hand, when the temperature of thermal treatment is higher than 1600° C. or the reaction time is longer than 60 min, the acicular particles 3 are produced rapidly, and thus pores are clogged, undesirably decreasing filtration efficiency. Thus, the temperature of thermal treatment preferably ranges from 1400° C. to 1600° C., and the thermal treatment time preferably ranges from 20 min to 60 min.

### EXPERIMENTAL EXAMPLE

According to the present invention, the silicon carbide-based porous bodies were manufactured through the following examples and comparative examples, and the thermal impact resistance and filtration properties thereof were evaluated.

The SiC and Si particles respectively having predetermined purity were mixed with a binder and water, after which the mixture was extruded, thus producing a pre-molded product having a honeycombed shape. The pre-molded product was dried at 100° C., placed in a kiln, and then thermally treated.

The thermal impact resistance of the porous bodies manufactured through the above process was evaluated as follows. That is, the porous bodies were placed in an electric furnace at 1200° C., left therein for 30 min, and then subjected to water cooling, and the above procedures were repeated four times. The bending strength of the test pieces before and after the thermal impact test was measured, and the ratios thereof were used to calculate the thermal impact resistance of the test pieces. Further, the filtration properties of the fine carbon soot particles were evaluated as follows. That is, the whole surface of the manufactured porous body was exposed to a stream of argon gas containing 1 vol % of carbon particles having an average particle size of 0.1 μm, which flows at a flux of 200 ml, for 30 min, after which the weight of the porous body was measured and the weight increase due to the adsorption of carbon particles was determined, and thus filtration efficiency was calculated. Table 1 below shows fabrication conditions of silicon carbide-based porous bodies of the examples and comparative examples and the thermal impact resistance and filtration indices of the fabricated porous bodies. The index of thermal impact resistance and the filtration index were converted into a percentage, wherein the results of the test pieces of Comparative Examples 1 and 6 were set as standards equal to 100, respectively, as shown in Table 1 below.

TABLE 1

| | Material | N₂ Gas | Thermal | Thermal | Index of Thermal | |
|---|---|---|---|---|---|---|
| | Purity | Pressure | Treatment | Treatment | Impact | Filtration |
| No. | (%) | (atm) | Temp.(° C.) | Time (min) | Resistance | Index |
| C. Ex. 1 | 90 | 1.1 | 1500 | 60 | 100 | 155 |
| C. Ex. 2 | 99.9 | 1.1 | 1500 | 60 | 90 | 150 |
| C. Ex. 3 | 98 | 0.1 | 1500 | 60 | 140 | 96 |
| C. Ex. 4 | 98 | 3 | 1500 | 60 | 145 | 102 |
| C. Ex. 5 | 98 | 1.1 | 1300 | 60 | 90 | 98 |
| C. Ex. 6 | 98 | 1.1 | 1700 | 60 | 155 | 100 |
| C. Ex. 7 | 98 | 1.1 | 1500 | 10 | 120 | 95 |
| C. Ex. 8 | 98 | 1.1 | 1500 | 120 | 150 | 100 |
| Ex. 1 | 98 | 1.1 | 1500 | 50 | 150 | 160 |
| Ex. 2 | 97 | 1.2 | 1480 | 60 | 160 | 155 |

As is apparent from Table 1, the silicon carbide-based porous bodies fabricated in the examples of the present invention exhibited high filtration efficiency and thermal impact resistance. In contrast, the silicon carbide-based porous bodies fabricated in the comparative examples satisfied neither filtration efficiency nor thermal impact resistance.

### INDUSTRIAL APPLICABILITY

According to the present invention, a silicon carbide-based porous body having superior thermal impact resistance and increased filtration properties can be provided, thereby greatly increasing the performance of a porous filter in terms of industrial purposes.

1. A silicon carbide-based porous body, which is formed by burning silicon carbide-based particles having a purity of 95% to 99%, and which comprises Si-N- or Si-N-O-based acicular particles grown to have a needle shape on surfaces defining pores in the porous body.

2. The silicon carbide-based porous body according to claim 1, wherein the silicon carbide-based particles comprise SiC and/or Si particles.

3. A method of fabricating a silicon carbide-based porous body, comprising:
forming a pre-molded product using silicon carbide-based particles having a purity of 95% to 99%; and
thermally treating the pre-molded product in a kiln in a nitrogen atmosphere having partial pressure ranging from 0.5 atm to 2 atm, thus growing Si-N- or Si-N-O-based acicular particles having a needle shape on surfaces defining pores in the porous body.

4. The method according to claim 3, wherein the silicon carbide-based particles comprise SiC and/or Si particles.

5. The method according to claim 3, wherein the thermally treating is conducted at a temperature ranging from 1400° C. to 1600° C. for a period of time ranging from 20 min to 60 min.
